(19) United States
(12) Patent Application Publication
(10) Pub. No.: US 2024/0186343 A1
(43) Pub. Date: Jun. 6, 2024

(54) IMAGING DEVICE

(71) Applicant: Panasonic Intellectual Property Management Co., Ltd., Osaka (JP)

(72) Inventors: JUNJI HIRASE, Osaka (JP); AKIO NAKAJUN, Toyama (JP); YUUKO TOMEKAWA, Osaka (JP)

(21) Appl. No.: 18/442,157

(22) Filed: Feb. 15, 2024

Related U.S. Application Data
(63) Continuation of application No. PCT/JP2022/031065, filed on Aug. 17, 2022.

(30) Foreign Application Priority Data
Sep. 3, 2021 (JP) 2021-143892

(51) Int. Cl. H01L 27/146; H01L 31/0224; H01L 31/055

(52) U.S. Cl. CPC H01L 27/14605; H01L 27/14618; H01L 27/14623; H01L 31/022425; H01L 31/055

(57) ABSTRACT

An imaging device includes: a semiconductor substrate; an effective pixel region including an effective pixel; a non-effective pixel region that is located around the effective pixel region and that does not include the effective pixel; a photoelectric converter that is located above the semiconductor substrate and that includes a first portion located in the effective pixel region and a second portion located in the non-effective pixel region; a light-shielding film that is located above the second portion of the photoelectric converter and that contains titanium or tantalum; and a functional film that is located on the light-shielding film and that is in contact with the light-shielding film. The functional film has a thickness less than a thickness of the light-shielding film.

### BACKGROUND

### 1. Technical Field

The present disclosure relates to an imaging device.

### 2. Description of the Related Art

Charge coupled device (CCD) image sensors and complementary metal oxide semiconductor (CMOS) image sensors are widely used in digital cameras and the like. As is well known, these image sensors have photodiodes formed on a semiconductor substrate.

A structure has been proposed in which a photoelectric converter including a photoelectric conversion layer is disposed above a semiconductor substrate (see, for example, Japanese Unexamined Patent Application Publication No. 2012-209342 and U.S. Pat. No. 10,868,068). An imaging device having such a configuration is sometimes called a laminated imaging device.

In a laminated imaging device, charges generated by photoelectric conversion are stored in a charge storage region. A signal corresponding to the amount of charges stored in the charge storage region is read through a CCD circuit or a CMOS circuit formed on a semiconductor substrate.

### SUMMARY

In one general aspect, the techniques disclosed here feature an imaging device including: a semiconductor substrate; an effective pixel region including an effective pixel; a non-effective pixel region that is located around the effective pixel region and that does not include the effective pixel; a photoelectric converter that is located above the semiconductor substrate and that includes a first portion located in the effective pixel region and a second portion located in the non-effective pixel region; a light-shielding film that is located above the second portion of the photoelectric converter and that contains titanium or tantalum; and a functional film that is located on the light-shielding film and that is in contact with the light-shielding film. The functional film has a thickness less than a thickness of the light-shielding film.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a sectional view of the vicinity of an end portion of a photoelectric converter included in an imaging device according to an embodiment;

FIG. 2A is a sectional view schematically illustrating a laminate structure of a light-shielding film, a functional film, and a protective film as well as incident light and reflected light according to the embodiment;

FIG. 2B is a sectional view schematically illustrating a laminate structure of a light-shielding film, a functional film, and a protective film as well as incident light and reflected light according to a comparative example;

FIG. 3 is a graph illustrating the reflectance of the laminate structures illustrated in FIGS. 2A and 2B;

FIG. 4 is a graph illustrating film thickness dependence of the transmittance of a titanium film and a titanium nitride film;

FIG. 5 is a circuit diagram illustrating a circuit configuration of the imaging device according to the embodiment; and

FIG. 6 is a sectional view of a unit pixel in the imaging device according to the embodiment.

### DETAILED DESCRIPTIONS

### Summary of Present Disclosure

An imaging device according to an aspect of the present disclosure includes: a semiconductor substrate; an effective pixel region including an effective pixel; a non-effective pixel region that is located around the effective pixel region and that does not include the effective pixel; a photoelectric converter that is located above the semiconductor substrate and that includes a first portion located in the effective pixel region and a second portion located in the non-effective pixel region; a light-shielding film that is located above the second portion of the photoelectric converter and that contains titanium or tantalum; and a functional film that is located on the light-shielding film and that is in contact with the light-shielding film. The functional film has a thickness less than a thickness of the light-shielding film.

Titanium or tantalum can be deposited at low temperatures. This makes it possible to prevent the photoelectric converter from deteriorating at high temperatures when forming the light-shielding film, thus suppressing deterioration of photoelectric conversion performance. The functional film provided can prevent the light-shielding film from deteriorating during subsequent processes and/or during use after completion of the product. The imaging device according to this aspect can thus prevent performance degradation.

For example, the imaging device according to the aspect of the present disclosure may further include: a protective film that is located on the functional film and that is in contact with the functional film. A reflectance of the functional film for light transmitted through the protective film may be less than a reflectance of the light-shielding film for light transmitted through the protective film when the protective film is in contact with the light-shielding film.

The protective film provided makes it possible to prevent the light-shielding film and the photoelectric converter from deteriorating during subsequent processes and/or during use after completion of the product. The functional film has low reflectance to light transmitted through the protective film, thus making it possible to suppress stray light reflected by the functional film. By suppressing the stray light, the occurrence of flare and/or coloring is suppressed. This makes it possible to prevent deterioration in image quality of images generated by the imaging device.

For example, the protective film may contain silicon oxynitride.

This makes it possible to realize a protective film that has high barrier properties against moisture and oxygen and is highly translucent.

For example, the functional film and the light-shielding film may contain the same metal element.

The light-shielding film and the functional film can thus be continuously formed using the same device. Since the light-shielding film does not need to be exposed to the atmosphere after the formation thereof, deterioration of the light-shielding film can be suppressed.

For example, the functional film may contain titanium nitride or tantalum nitride.

The functional film can thus exhibit high barrier properties for the light-shielding film containing titanium or tantalum.

For example, the photoelectric converter may be located between the semiconductor substrate and the light-shielding film.

A stacked image sensor can thus be realized.

For example, the thickness of the functional film may be less than half the thickness of the light-shielding film.

This reduces the thickness of the functional film, thus allowing the light-shielding film to effectively exert its light shielding function.

For example, the thickness of the light-shielding film may be greater than or equal to 200 nm.

This makes it possible to reduce transmittance of light, and thus sufficient light shielding performance can be achieved.

For example, the thickness of the functional film may be less than or equal to 30 nm.

This reduces the thickness of the functional film, thus allowing the light-shielding film to effectively exert its light shielding function.

Hereinafter, embodiments of the present disclosure will be described in detail with reference to the drawings.

The embodiments described below all illustrate comprehensive or specific examples. The numerals, shapes, materials, constituent elements, the arrangement and connections of the constituent elements, steps, order of the steps, and the like discussed in the following embodiments are only exemplary and are not construed to limit the present disclosure. Among the constituent elements in the following embodiments, constituent elements not described in an independent claim will be described as arbitrary constituent elements.

The drawings are schematic and not necessarily to scale. Therefore, for example, scales and the like do not necessarily match in each drawing. In addition, in each drawing, substantially the same configurations are denoted by the same reference numerals to eliminate or simplify overlapped description.

In this specification, terms indicating the relationship between elements such as parallel and perpendicular, terms indicating the shape of elements such as a rectangle, and numerical ranges are expressions including substantially the same ranges, for example, differences of about several percent, rather than expressions indicating strict meanings only.

In this specification, the terms “above” and “below” in a battery configuration do not refer to upward (vertically upward) and downward (vertically downward) directions in absolute spatial recognition, but are rather used as terms defined based on the incidence of light to an image sensor. Specifically, the light irradiation side is regarded as “above (upper side)”, while the light incidence side is regarded as “below (lower side)”. In addition, the terms “above” and “below” are applied not only to a case where two constituent elements are spaced apart from each other with another constituent element between the two constituent elements but also to a case where two constituent elements are arranged in close contact with each other.

In this specification, ordinal numbers, such as “first” and “second”, do not mean the number of constituent components or the order thereof but are used to avoid confusion between constituent components of the same type and discriminate the components unless otherwise specified.

### Embodiment 1

### 1. Configuration

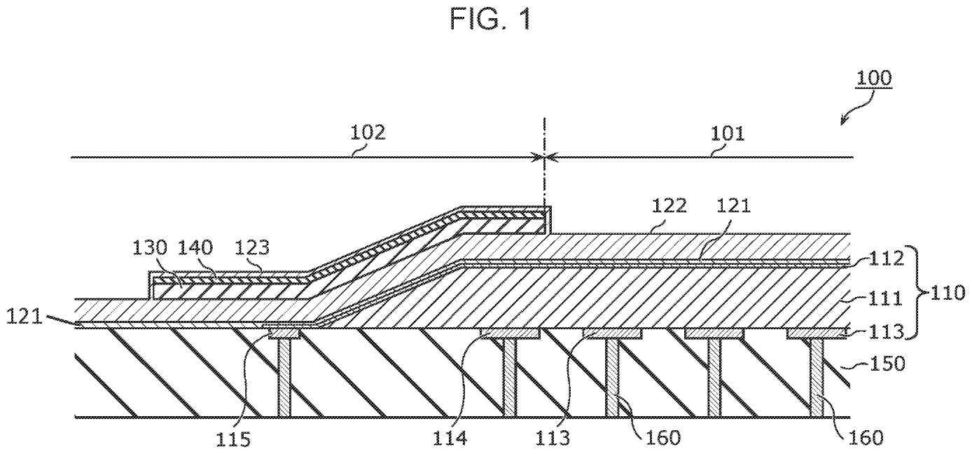

First, a configuration of a photoelectric converter and its surroundings in an imaging device according to an embodiment will be described with reference to FIG. 1.

FIG. 1 is a sectional view of the vicinity of an end portion of a photoelectric converter 110 included in an imaging device 100 according to this embodiment. As illustrated in FIG. 1, the imaging device 100 includes the photoelectric converter 110, protective films 121, 122, and 123, a light-shielding film 130, a functional film 140, an interlayer insulating layer 150, and a plurality of via conductors 160. The imaging device 100 also includes an effective pixel region 101 and a non-effective pixel region 102.

The effective pixel region 101 is a region that includes a plurality of effective pixels of the imaging device 100. The effective pixels correspond to pixels of an image generated by the imaging device 100. The effective pixels are arranged in a matrix of m rows and n columns. m and n are natural numbers of 2 or more. The effective pixel region 101 can be regarded as a rectangular region that circumscribes all of the effective pixels arranged in a circular pattern at the outermost periphery among the effective pixels arranged in m rows and n columns. That is, the effective pixel region 101 is a rectangular region in a plan view, for example, in which a plurality of pixel electrodes 113 are disposed. The plurality of pixel electrodes 113 are each a pixel electrode of the effective pixel.

The effective pixels may be arranged in one row or one column. That is, the imaging device 100 may be a line sensor. Alternatively, the imaging device 100 may include only one effective pixel.

The non-effective pixel region 102 is a region located around the effective pixel region 101. The non-effective pixel region 102 is, for example, a rectangular annular region surrounding the effective pixel region 101 in a plan view but is not limited thereto. The non-effective pixel region 102 does not need to surround the effective pixel region 101. Specifically, the non-effective pixel region 102 may be a linear region along one side of the effective pixel region 101, or an L-shaped region along two adjacent sides of the effective pixel region 101. The non-effective pixel region 102 may be provided along two opposite sides of the effective pixel region 101 so as to sandwich the effective pixel region 101.

The end portion of the photoelectric converter 110 is provided in the non-effective pixel region 102. In other words, the photoelectric converter 110 straddles the effective pixel region 101 and the non-effective pixel region 102. The photoelectric converter 110 includes a first portion located in the effective pixel region 101 and a second portion located in the non-effective pixel region 102. The photoelectric converter 110 is provided across the entire effective pixel region 101 in a plan view.

### 1-1. Photoelectric Converter

As illustrated in FIG. 1, the photoelectric converter 110 includes a photoelectric conversion layer 111, a Transparent electrode 112, and the plurality of pixel electrodes 113. The photoelectric converter 110 is provided on the interlayer insulating layer 150.

The interlayer insulating layer 150 is an insulating layer formed above a semiconductor substrate (not illustrated). A transistor and the like included in a signal processing circuit that processes signal charges generated by the photoelectric converter 110, for example, are formed on the semiconductor substrate. The interlayer insulating layer 150 has a single layer structure or a multilayer structure including a silicon oxide film, a silicon nitride film, or a tetraethyl orthosilicate (TEOS) film, for example, but is not particularly limited.

The photoelectric conversion layer 111 is located between the plurality of pixel electrodes 113 and the transparent electrode 112. The photoelectric conversion layer 111 is provided across the entire effective pixel region 101 in a plan view, and straddles the effective pixel region 101 and the non-effective pixel region 102. The photoelectric conversion layer 111 has its end portion tapered so that the film thickness gradually decreases within the non-effective pixel region 102, but the present disclosure is not limited thereto. In this event, the photoelectric conversion layer 111 has a fixed film thickness at least in a portion covering a pixel electrode 114, which is the same as that in a portion within the effective pixel region 101.

The photoelectric conversion layer 111 generates electron-hole pairs therein upon being irradiated with light. The electron-hole pair is separated into an electron and a hole by an electric field applied to the photoelectric conversion layer 111. The electron and hole move to the pixel electrode 113 and 114 side or the transparent electrode 112 side.

The photoelectric conversion layer 111 contains organic matter. Specifically, the photoelectric conversion layer 111 is formed using a photoelectric conversion material containing an organic material. When the photoelectric conversion material contains an organic material, the molecular design of the photoelectric conversion material can be relatively freely done so as to obtain desired photoelectric conversion characteristics. When the photoelectric conversion material contains an organic material, the photoelectric conversion layer 111 with excellent planarization properties can be easily formed by an application process using a solution containing the photoelectric conversion material. The organic material can be formed by vacuum deposition or application, for example.

When using an organic semiconductor material as the photoelectric conversion material, the photoelectric conversion layer 111 may be formed of a laminated film of a donor organic semiconductor material and an acceptor organic semiconductor material, or may be formed of a mixed film of these materials. As the donor organic semiconductor material and the acceptor organic semiconductor material, known organic semiconductor materials can be used. Alternatively, an inorganic material such as quantum dots including semiconductor nanocrystals may be used as the photoelectric conversion material.

The transparent electrode 112 is an electrode layer provided facing the plurality of pixel electrodes 113. The transparent electrode 112 collects charges having a polarity opposite to that of signal charges collected by the pixel electrodes 113. A predetermined voltage is applied to the transparent electrode 112. This causes a potential difference between the transparent electrode 112 and the plurality of pixel electrodes 113, thus applying an electric field to the photoelectric conversion layer 111. The transparent electrode 112 collects charges that move toward the transparent electrode 112 due to the electric field, among the holes and electrons generated in the photoelectric conversion layer 111.

The transparent electrode 112 has translucency to the light photoelectrically converted by the photoelectric conversion layer 111. Specifically, the transparent electrode 112 is a transparent electrode that is transparent to visible light. “Transparent” means that the transmittance to light is sufficiently high. For example, the transmittance of the transparent electrode 112 for a predetermined wavelength in the visible light band may be greater than 50%, greater than 60%, greater than 70%, greater than 80%, or greater than 90%.

The transparent electrode 112 is formed using an indium tin oxide (ITO), for example. The transparent electrode 112 has a film thickness of, for example, 10 nm to 50 nm, but is not limited thereto. The transparent electrode 112 may be, for example, another transparent oxide conductor film such as aluminum-doped zinc oxide (AZO) or gallium-doped zinc oxide (GZO), or a translucent metal thin film.

The transparent electrode 112 extends outward from the photoelectric conversion layer 111 in a plan view. The transparent electrode 112 is connected to a terminal electrode 115 in this extended portion. The terminal electrode 115 is provided in the non-effective pixel region 102 and is electrically connected to the transparent electrode 112. The terminal electrode 115 is a terminal for feeding power to the transparent electrode 112. As a material for the terminal electrode 115, a conductive material such as metal, metal oxide, metal nitride, or conductive polysilicon is used.

In this embodiment, the transparent electrode 112 and the photoelectric conversion layer 111 are configured in a single plate shape that covers all the pixel electrodes 113, but are not limited to this configuration. At least one of the transparent electrode 112 and the photoelectric conversion layer 111 may be divided for each pixel, each plurality of pixels, each pixel row, or each pixel column.

The plurality of pixel electrodes 113 are electrode layers for collecting signal charges generated in the photoelectric conversion layer 111. As described above, the pixel electrode 113 is the pixel electrode of the effective pixel. In this embodiment, the pixel electrode 114 is also provided in the non-effective pixel region 102. The pixel electrode 114 is a pixel electrode of a pixel other than the effective pixel. Specifically, the pixel electrode 114 is a pixel electrode of a pixel for generating a black level. A plurality of pixel electrodes 114 may be provided in one row or one column. Note that a pixel electrode for a dummy pixel may be provided around the pixel electrode 114. For example, one or more pixel electrodes for dummy pixels are provided between the pixel electrode 114 and the pixel electrode 113. Alternatively, a plurality of pixel electrodes for dummy pixels may be provided so as to surround the pixel electrode 114, for example.

The pixel electrodes 113 and 114 and the terminal electrode 115 can be formed using the same material. As the material for the pixel electrodes 113 and 114 and the terminal electrode 115, for example, a conductive material such as metal, metal oxide, metal nitride, or conductive polysilicon is used. Here, the metal is, for example, aluminum, silver, copper, titanium, tantalum, tungsten or the like. The metal nitride is, for example, titanium nitride, tantalum nitride or the like. The conductive polysilicon is polysilicon that is made conductive by adding impurities thereto. As an example, the pixel electrodes 113 and 114 have a laminate structure of titanium and titanium nitride, and each have a film thickness of, for example, about 30 nm to 50 nm, but are not limited thereto.

As illustrated in FIG. 1, the via conductor 160 is connected to the lower surface of each of the plurality of pixel electrodes 113 and 114. The via conductor 160 is a part of wiring that electrically connects the corresponding pixel electrode 113 or 114 to the signal processing circuit. The via conductor 160 functions as part of the charge storage region. As a material for the via conductor 160, a conductive material such as metal, metal oxide, metal nitride, or conductive polysilicon is used.

### 1-2. Protective Film, Light-Shielding Film and Functional Film

As illustrated in FIG. 1, the protective films 121 and 122 are provided in the effective pixel region 101 and the non-effective pixel region 102 so as to cover the photoelectric converter 110. The protective films 121 and 122 are provided to protect the photoelectric converter 110 from moisture, oxygen, and the like. The protective film 121 is provided on and in contact with the transparent electrode 112. The protective film 122 is provided on and in contact with the protective film 121.

The protective film 121 has a film thickness smaller than that of the protective film 122. The protective film 121 has a small film thickness and thus can be formed by a film forming method excellent in surface shape followability, such as atomic layer deposition (ALD), for example. The protective film 121 can therefore cover the upper surface of the photoelectric converter 110 without any gaps, thus improving the protection performance for the photoelectric converter 110.

The protective film 122 has a large film thickness and thus has high barrier performance against moisture and oxygen. By laminating the protective film 122 on the protective film 121 having a small film thickness, the protection performance for the photoelectric converter 110 can be further improved. The protective film 122 is formed by a film forming method suitable for thickening the film, such as plasma chemical vapor deposition (CVD), for example.

The protective film 121 is an aluminum oxide film (AlO film) having a thickness of 50 nm or less, for example. The protective film 122 is a silicon oxynitride film (SiON film) having a thickness of 300 nm or less, for example. As with the transparent electrode 112, the protective films 121 and 122 have translucency to the light photoelectrically converted by the photoelectric conversion layer 111.

Note that at least one of the protective films 121 and 122 does not need to be provided. The materials constituting the protective films 121 and 122 are not particularly limited as long as they are translucent and can exhibit protection performance.

The light-shielding film 130 is located above the photoelectric converter 110 in the non-effective pixel region 102. Specifically, the light-shielding film 130 is in contact with the protective film 122 above the protective film 122. The light-shielding film 130 overlaps the pixel electrode 114 in a plan view. That is, the light-shielding film 130 inhibits light from entering the upper portion of the pixel electrode 114 in the photoelectric conversion layer 111.

In this embodiment, the light-shielding film 130 overlaps the terminal electrode 115 in a plan view. The light-shielding film 130 may be provided across substantially the entire non-effective pixel region 102. Peripheral circuits (to be described in detail later) of the imaging device 100 are disposed in the non-effective pixel region 102. The light-shielding film 130 can also inhibit light from entering transistors and the like included in the peripheral circuits. This can prevent the generation of unnecessary current that causes noise, thus suppressing deterioration in image quality.

The light-shielding film 130 contains titanium (Ti) or tantalum (Ta). Specifically, the light-shielding film 130 is a metal film made of titanium alone or a metal film made of tantalum alone. A metal film made of titanium alone or tantalum alone can be formed by vapor deposition at about 200° C. This can prevent the photoelectric converter containing organic matter or quantum dots such as semiconductor nanocrystals from deteriorating at high temperatures when forming the light-shielding film, thus suppressing deterioration in photoelectric conversion performance. Note that the light-shielding film 130 may contain unavoidable impurity elements that cannot be prevented from being mixed during manufacturing.

The functional film 140 is in contact with the light-shielding film 130 on the light-shielding film 130. In this embodiment, the functional film 140 contacts and covers the entire upper surface of the light-shielding film 130. For example, the shape and size of the functional film 140 in a plan view are the same as the shape and size of the light-shielding film 130 in a plan view.

The functional film 140 is a deterioration preventing film that prevents the light-shielding film 130 from deteriorating during the process and/or during use after completion of the product. For example, the light shielding performance deteriorates when the light-shielding film 130 made of Ti is oxidized by exposure to oxygen or the like during or after the process. There is also a risk that the light-shielding film 130 may deteriorate when exposure to the atmosphere or the like causes moisture to come into direct contact with the light-shielding film 130. The functional film 140 can prevent the light-shielding film 130 from coming into contact with oxygen and moisture, thus suppressing oxidation of the light-shielding film 130 and preventing deterioration in light-shielding performance.

The functional film 140 is formed using a material that is chemically more stable than the light-shielding film 130. Specifically, the functional film 140 contains titanium nitride (TiN) or tantalum nitride (TaN). The functional film 140 contains the same metal element as the light-shielding film 130. When the light-shielding film 130 is a Ti film, for example, the functional film 140 is a TiN film. When the light-shielding film 130 is a Ta film, the functional film 140 is a TaN film.

The functional film 140 has a thickness smaller than that of the light-shielding film 130. For example, the thickness of the functional film 140 is less than or equal to half the thickness of the light-shielding film 130. The functional film 140 is, for example, a TiN film having a thickness of 100 nm. The light-shielding film 130 is, for example, a Ti film having a thickness of 280 nm. By increasing the thickness of the light-shielding film 130 with high light shielding performance, the light shielding performance can be effectively exerted.

The light-shielding film 130 and the functional film 140 are formed by forming each film by sputtering, vapor deposition or the like and then patterning each film into a predetermined shape. The light-shielding film 130 and the functional film 140 can be continuously formed using a same film forming apparatus. The light-shielding film 130 and the functional film 140 can be patterned all at once. Therefore, the light-shielding film 130 and the functional film 140 have substantially the same shape in a plan view. That is, the functional film 140 can cover the entire light-shielding film 130 so that the light-shielding film 130 is not exposed. The patterning is performed by photolithography, etching, lift-off or the like.

A protective film 123 is in contact with the functional film 140 on the functional film 140. In this embodiment, the protective film 123 contacts and covers the entire upper surface of the functional film 140 and the end faces of the functional film 140 and light-shielding film 130. As with the protective films 121 and 122, the protective film 123 may be provided not only in the non-effective pixel region 102 but also in the effective pixel region 101. The protective film 123 is provided to protect the light-shielding film 130 and the photoelectric converter 110 from moisture, oxygen, and the like.

The protective film 123 contains the same material as the protective film 122. Specifically, the protective film 123 contains silicon oxynitride (SiON). The protective film 123 is, for example, a SiON film having a thickness of 100 nm or less. The protective film 123 is formed by plasma CVD or the like, for example.

### 2. Optical Characteristics of Light-Shielding Film and Functional Film

Next, optical characteristics of the light-shielding film 130 and the functional film 140 will be described.

### 2-1. Reflectance

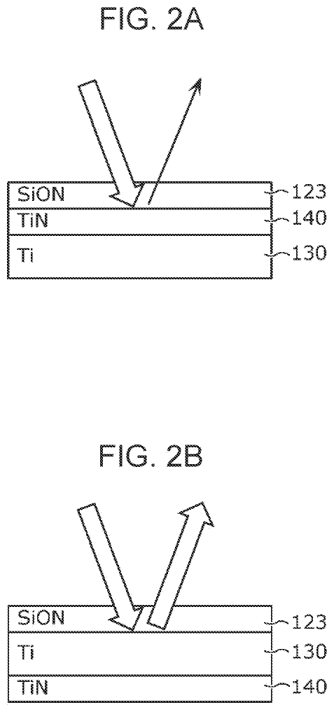

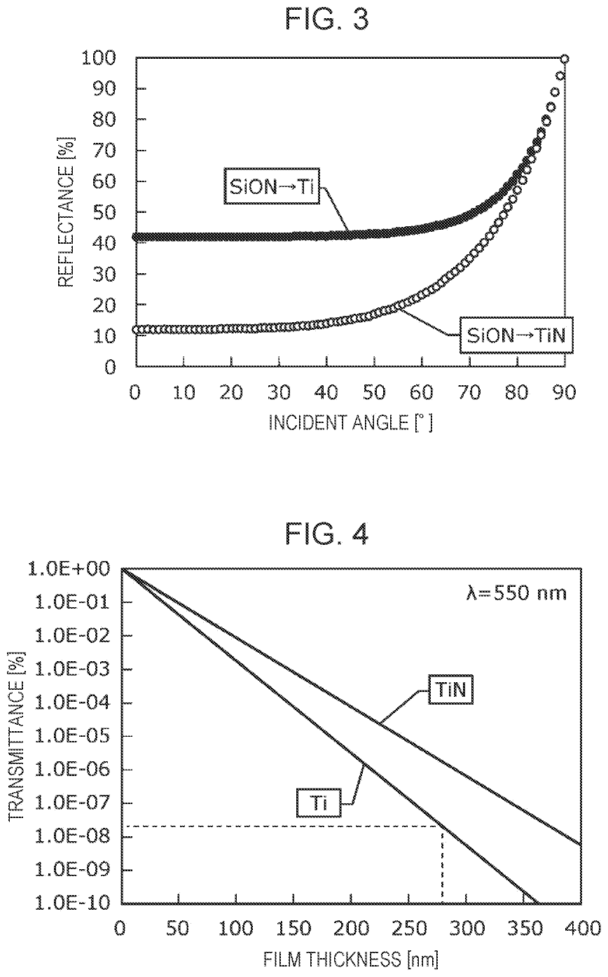

First, the reflectance of the laminate structure of the light-shielding film 130 and the functional film 140 will be described with reference to FIGS. 2A, 2B, and 3. FIGS. 2A and 2B are sectional views schematically illustrating the laminate structures of the light-shielding film 130, the functional film 140, and the protective film 123, as well as incident light and reflected light, according to the embodiment and a comparative example, respectively.

In this embodiment, as illustrated in FIG. 2A, the light-shielding film 130, the functional film 140, and the protective film 123 are stacked in this order from the semiconductor substrate (not illustrated) side (that is, from the interlayer insulating layer 150 side). In the comparative example, on the other hand, the functional film 140, the light-shielding film 130, and the protective film 123 are stacked in this order as illustrated in FIG. 2B. That is, the stacking order of the light-shielding film 130 and the functional film 140 is reversed between FIGS. 2A and 2B. Here, the protective film 123, the functional film 140, and the light-shielding film 130 are a SiON film, a TiN film, and a Ti film, respectively.

FIG. 3 is a graph illustrating the reflectance of the laminate structures illustrated in FIGS. 2A and 2B. In FIG. 3, the horizontal axis represents the incident angle of light with respect to the laminate structure. The vertical axis represents the reflectance of light. The reflectance is the ratio of reflected light intensity to incident light intensity.

“SiON→TIN” in FIG. 3 represents the reflectance when light enters the functional film 140 made of TiN from the protective film 123 made of SiON, as illustrated in FIG. 2A. “SiON→Ti” in FIG. 3 represents the reflectance when light enters the light-shielding film 130 made of Ti from the protective film 123 made of SiON, as illustrated in FIG. 2B.

As illustrated in FIG. 3, the reflectance of the functional film 140 for the light transmitted through the protective film 123 is smaller than the reflectance of the light-shielding film 130 for the light transmitted through the protective film 123. Note that the “reflectance of film B for light transmitted through film A” refers to the reflectance of film B when light enters from the film A side in a case where film A and film B are laminated in contact with each other.

When the incident angle is in the range of 0° to 40°, the reflectance of the functional film 140 for the light transmitted through the protective film 123 and the reflectance of the light-shielding film 130 for the light transmitted through the protective film 123 are both substantially constant. The reflectance of the functional film 140 for the light transmitted through the protective film 123 is about one-fourth of the reflectance of the light-shielding film 130 for the light transmitted through the protective film 123. That is, in the structure in which the protective film 123 and the functional film 140 are laminated as illustrated in FIG. 2A, reflection of obliquely incident light is more suppressed than in the structure illustrated in FIG. 2B.

The reflectance of the functional film 140 for light transmitted through the protective film 123 gradually increases from a range where the incident angle exceeds 40°. Even when the incident angle is in the range of 40° to 60°, the reflectance of the functional film 140 for the light transmitted through the protective film 123 is about one-fourth to one-half of the reflectance of the light-shielding film 130 for the light transmitted through the protective film 123. When the incident angle is in the range of 60° to 80°, the reflectance of the functional film 140 for the light transmitted through the protective film 123 is smaller than the reflectance of the light-shielding film 130 for the light transmitted through the protective film 123, although the difference is becoming smaller.

The laminate structure according to this embodiment illustrated in FIG. 2A can thus suppress the reflection of obliquely incident light, in particular. When oblique light made incident on the non-effective pixel region 102 is reflected, the light is reflected by a color filter and/or an optical element (not illustrated), such as a microlens, and easily enters the effective pixel region 101 as stray light. By suppressing the reflection of this obliquely incident light, stray light can be suppressed and deterioration in image quality can be prevented.

The combination of the light-shielding film 130 and the functional film 140 is not limited to the Ti film and TiN film, and a Ta film and a TaN film can also be used.

Table 1 shows the refractive index n, extinction coefficient k, and reflectance R of materials that can be used as the light-shielding film 130, the functional film 140, and the protective film 123.

TABLE 1

| | Refractive | Extinction | Reflectance R (disposed |
|---|---|---|---|
| Material | index n | coefficient k | directly below SiON) |
| Ti | 2.4 | 3.37 | 0.42 |
| TiN | 1.76 | 1.29 | 0.12 |
| Ta | 1.72 | 2.08 | 0.27 |
| TaN | 2.48 | 1.7 | 0.17 |
| SiON | 1.69 | 0 | 0 |

The reflectance R is the reflectance of a film made of a target material with respect to light transmitted through an SiON film. The reflectance R is calculated based on the following formula (1).

$$R = \frac{{( n - 169 )}^{2} + {k}^{2}}{{( n + 1.69 )}^{2} + {k}^{2}} \qquad ( 1 )$$

As shown in Table 1, the reflectance of light transmitted through the SiON film is smaller in TiN than in Ti. Similarly, the reflectance of light transmitted through the SiON film is smaller in TaN than in Ta. Therefore, the reflectance can be suppressed by forming the functional film 140 with TiN or TaN.

### 2-2. Transmittance (Light-Shielding Rate)

Next, the transmittance of the laminate structure of the light-shielding film 130 and the functional film 140 will be described with reference to FIG. 4.

FIG. 4 is a graph illustrating the film thickness dependence of the transmittance of the Ti film and the TiN film. In FIG. 4, the horizontal axis represents the thickness of each film. The vertical axis represents the transmittance of each film in logarithmic form. The transmittance is the intensity of light transmitted through each film and emitted, relative to the intensity of incident light. The lower the transmittance, the more suppressed the transmission of light, that is, the higher the light-shielding property.

As illustrated in FIG. 4, the transmittance of both the Ti film and the TiN film decreases as the film thickness increases. When compared with the same film thickness, the transmittance of the Ti film is lower than that of the TiN film.

Pixels for generating a black level are required to have light-shielding performance such that the intensity of transmitted light is lower than the intensity of incident light by five to ten orders of magnitude. In this embodiment, as an example, the thickness of the Ti film is designed to achieve a reduction of about eight orders of magnitude. Specifically, a reduction of eight orders of magnitude is achieved by setting the thickness of the Ti film to 280 nm.

The thickness of each of the light-shielding film 130 and the functional film 140 is not limited to the example described above. The thickness of each film may be adjusted as appropriate to achieve desired light-shielding performance. For example, the thickness of the functional film 140 is more than or equal to 10 nm. This enables the functional film 140 to exert its function to protect the light-shielding film 130. For example, the thickness of the functional film 140 may be less than or equal to 50 nm or may be less than or equal to 30 nm. The functional film 140 low in light-shielding performance is thus provided for the purpose of exerting its function to protect the light-shielding film 130. This enables the light-shielding film 130 to effectively exert its light-shielding performance.

The thickness of the light-shielding film 130 is adjusted as appropriate depending on the required light-shielding performance. For example, the thickness of the light-shielding film 130 is more than or equal to 200 nm, which can reduce the transmittance by about six orders of magnitude. As illustrated in FIG. 4, when the thickness of the light-shielding film 130 made of Ti is 350 nm, for example, the transmittance can be reduced by nine or more orders of magnitude, but the thickness thereof may be more than or equal to 350 nm.

The combination of the Ti film and the TiN film has been described above, but the Ta film and the TaN film also have the same characteristics as those of the Ti film and the TiN film. Therefore, the Ta film and the TaN film can be used instead of the Ti film and the TiN film.

### 3. Imaging Device

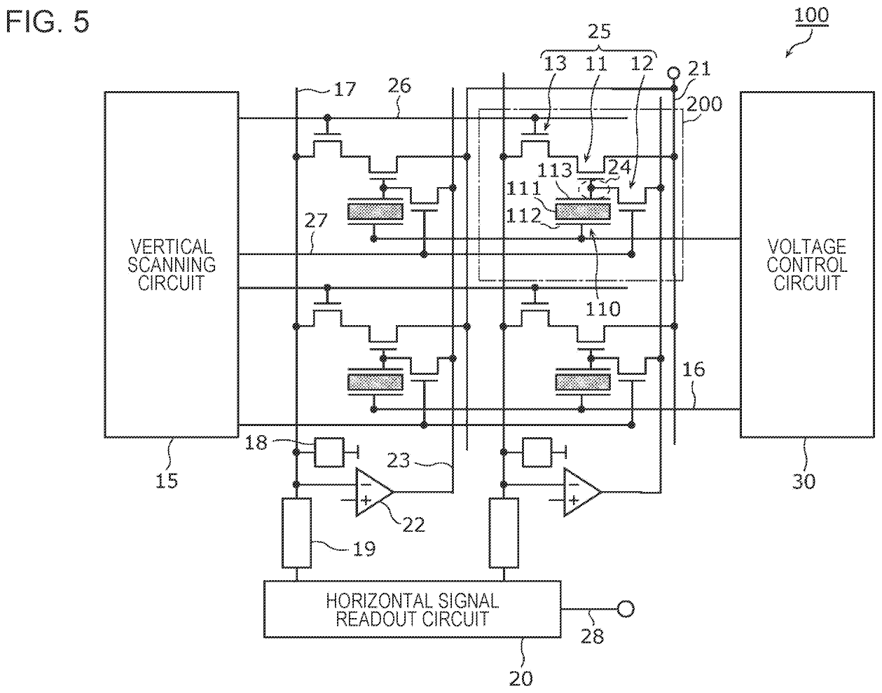

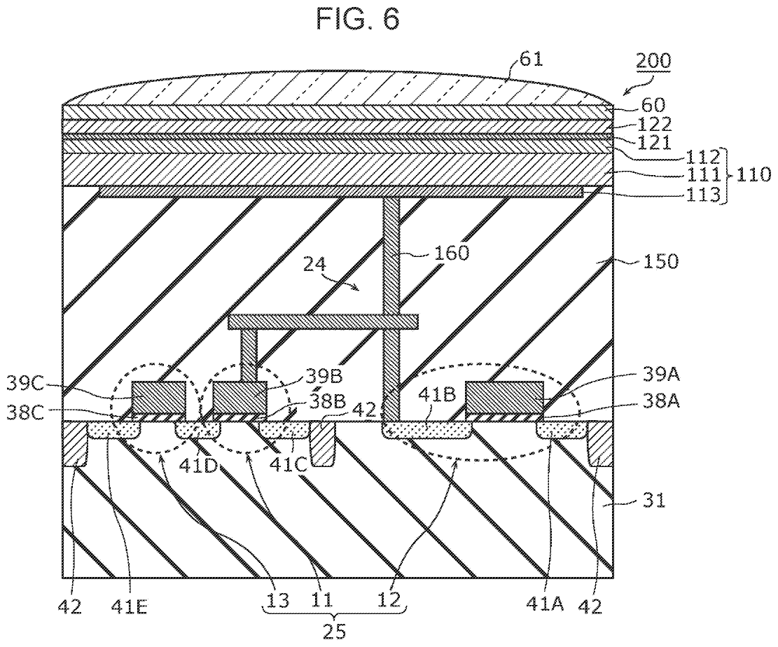

Next, the imaging device according to this embodiment will be described with reference to FIGS. 5 and 6.

FIG. 5 is a circuit diagram illustrating a circuit configuration of the imaging device 100 according to this embodiment. FIG. 6 is a sectional view of a unit pixel 200 in the imaging device 100 according to this embodiment.

### 3-1. Circuit Configuration

First, the circuit configuration of the imaging device 100 according to this embodiment will be described. As illustrated in FIG. 5, the imaging device 100 includes a plurality of unit pixels 200 and peripheral circuits. The plurality of unit pixels 200 each include a charge detection circuit 25, a photoelectric converter 110, and a charge storage node 24 electrically connected to the charge detection circuit 25 and the photoelectric converter 110.

The imaging device 100 is, for example, an organic image sensor realized by a single-chip integrated circuit, and has a pixel array including the plurality of unit pixels 200 arranged two-dimensionally. The plurality of unit pixels 200 are, for example, effective pixels each including the pixel electrode 113. The plurality of unit pixels 200 may include a pixel for generating a black level, which includes the pixel electrode 114.

Each unit pixel 200 includes the charge storage node 24 electrically connected to the photoelectric converter 110 and the charge detection circuit 25. The charge detection circuit 25 includes an amplifier transistor 11, a reset transistor 12, and an address transistor 13.

As described above, the photoelectric converter 110 includes the pixel electrode 113, the photoelectric conversion layer 111, and the transparent electrode 112. A predetermined voltage is applied to the transparent electrode 112 from a voltage control circuit 30 through a transparent electrode signal line 16.

The pixel electrode 113 is connected to a gate electrode 39B (see FIG. 6) of the amplifier transistor 11. Signal charges collected by the pixel electrode 113 are stored in the charge storage node 24 located between the pixel electrode 113 and the gate electrode 39B of the amplifier transistor 11. The signal charges are holes in this embodiment but may be electrons.

The signal charges stored in the charge storage node 24 are applied to the gate electrode 39B of the amplifier transistor 11 as a voltage corresponding to the amount of signal charges. The amplifier transistor 11 amplifies this voltage. The amplified voltage is selectively read by the address transistor 13 as a signal voltage. The reset transistor 12 has one of its source electrode and drain electrode connected to the pixel electrode 113, and resets the signal charges stored in the charge storage node 24. In other words, the reset transistor 12 resets the potentials of the gate electrode 39B of the amplifier transistor 11 and the pixel electrode 113.

To selectively perform the above operations in the plurality of unit pixels 200, the imaging device 100 includes a power supply wiring 21, a vertical signal line 17, an address signal line 26, and a reset signal line 27, as illustrated in FIG. 5. These lines are connected to each unit pixel 200, respectively. Specifically, the power supply wiring 21 is connected to one of a source electrode and a drain electrode of the amplifier transistor 11. The vertical signal line 17 is connected to one of a source electrode and a drain electrode of the address transistor 13. The address signal line 26 is connected to a gate electrode 39C (see FIG. 6) of the address transistor 13. The reset signal line 27 is connected to a gate electrode 39A (see FIG. 6) of the reset transistor 12.

The peripheral circuits include a vertical scanning circuit 15, a horizontal signal readout circuit 20, a plurality of column signal processing circuits 19, a plurality of load circuits 18, a plurality of differential amplifiers 22, and the voltage control circuit 30. The vertical scanning circuit 15 is also referred to as a row scanning circuit. The horizontal signal readout circuit 20 is also referred to as a column scanning circuit. The column signal processing circuit 19 is also referred to as a row signal storage circuit. The differential amplifier 22 is also referred to as a feedback amplifier.

The vertical scanning circuit 15 is connected to the address signal line 26 and the reset signal line 27. The vertical scanning circuit 15 selects the plurality of unit pixels 200 arranged in each row on a row-by-row basis to read the signal voltage and reset the potential of the pixel electrode 113. The power supply wiring 21, which is a source follower power supply, supplies a predetermined power supply voltage to each unit pixel 200. The horizontal signal readout circuit 20 is electrically connected to the plurality of column signal processing circuits 19. The column signal processing circuit 19 is electrically connected to the unit pixels 200 arranged in each column through the vertical signal line 17 corresponding to each column. The load circuit 18 is electrically connected to each vertical signal line 17. The load circuit 18 and the amplifier transistor 11 form a source follower circuit.

A plurality of differential amplifiers 22 are provided corresponding to each column. The differential amplifier 22 has its negative input terminal connected to the corresponding vertical signal line 17. The differential amplifier 22 has its output terminal connected to the unit pixel 200 through a feedback line 23 corresponding to each column.

The vertical scanning circuit 15 applies a row selection signal for controlling on and off of the address transistor 13 to the gate electrode 39C of the address transistor 13 through the address signal line 26. A row to be read is thus scanned and selected. A signal voltage is read from the unit pixel 200 in the selected row to the vertical signal line 17. The vertical scanning circuit 15 applies a reset signal for controlling on and off of the reset transistor 12 to the gate electrode 39A of the reset transistor 12 through the reset signal line 27. A row of unit pixels 200 to be subjected to the reset operation is thus selected. The vertical signal line 17 transmits the signal voltage read from the unit pixel 200 selected by the vertical scanning circuit 15 to the column signal processing circuit 19.

The column signal processing circuit 19 performs noise suppression signal processing typified by correlated double sampling, analog-to-digital conversion (AD conversion), and the like.

The horizontal signal readout circuit 20 sequentially reads signals from the plurality of column signal processing circuits 19 to a horizontal common signal line 28.

The differential amplifier 22 is connected to the other of the source and drain electrodes of the reset transistor 12, which is not connected to the pixel electrode 113, through the feedback line 23. Therefore, the differential amplifier 22 receives the output value from the address transistor 13 at its negative input terminal when the address transistor 13 and the reset transistor 12 are in a conductive state. The differential amplifier 22 performs a feedback operation so that the gate potential of the amplifier transistor 11 becomes a predetermined feedback voltage. The feedback voltage means an output voltage of the differential amplifier 22.

The voltage control circuit 30 may generate a constant control voltage or may generate a plurality of control voltages with different values. For example, the voltage control circuit 30 may generate two or more control voltages with different values, or may generate a control voltage that continuously changes within a predetermined range. The voltage control circuit 30 determines a value of a control voltage to be generated, based on a command from an operator who operates the imaging device 100 or a command from another controller or the like included in the imaging device 100, and then generates the control voltage with the determined value. The voltage control circuit 30 is provided outside a photosensitive region as part of the peripheral circuits. The photosensitive region is substantially the same as the effective pixel region.

For example, the voltage control circuit 30 generates two or more different control voltages and apply these control voltages to the transparent electrode 112, thereby changing spectral sensitivity characteristics of the photoelectric conversion layer 111. This change in spectral sensitivity characteristics includes a spectral sensitivity characteristic in which the sensitivity of the photoelectric conversion layer 111 to the light to be detected becomes zero. Therefore, in the imaging device 100, for example, the voltage control circuit 30 applies a control voltage that causes the sensitivity of the photoelectric conversion layer 111 to become zero to the transparent electrode 112 while the unit pixels 200 read detection signals row by row. This makes it possible to substantially eliminate the influence of incident light upon reading the detection signals. Therefore, a global shutter operation can be realized even when the detection signals are substantially read row by row.

In this embodiment, as illustrated in FIG. 5, the voltage control circuit 30 applies a control voltage to the transparent electrodes 112 of the unit pixels 200 arranged in the row direction through the transparent electrode signal line 16. The voltage between the pixel electrode 113 and the transparent electrode 112 is thus changed to switch the spectral sensitivity characteristics in the photoelectric converter 110. Alternatively, the voltage control circuit 30 realizes an electronic shutter operation by applying a control voltage so as to obtain a spectral sensitivity characteristic in which the sensitivity to light becomes zero at a predetermined timing during imaging. The voltage control circuit 30 may apply a control voltage to the pixel electrode 113.

To irradiate the photoelectric converter 110 with light and cause the pixel electrode 113 to collect holes as signal charges, the transparent electrode 112 is set to have a potential higher than that of the pixel electrode 113. This causes the holes to move toward the pixel electrode 113. In this event, the moving direction of the holes is the same as the direction in which a current flows. Therefore, the current flows from the transparent electrode 112 to the pixel electrode 113. To irradiate the photoelectric converter 110 with light and cause the pixel electrode 113 to collect electrons as signal charges, the transparent electrode 112 is set to have a potential lower than that of the pixel electrode 113. In this event, a current flows from the pixel electrode 113 to the transparent electrode 112.

### 3-2. Cross-Sectional Configuration

Next, an example of a specific cross-sectional configuration of the unit pixel 200 in the imaging device 100 will be described with reference to FIG. 6. As illustrated in FIG. 6, the unit pixel 200 includes a semiconductor substrate 31, the charge detection circuit 25, the photoelectric converter 110, and the charge storage node 24. The plurality of unit pixels 200 are formed on the semiconductor substrate 31. For example, the photoelectric converter 110 is provided above the semiconductor substrate 31. The charge detection circuit 25 is provided in and on the semiconductor substrate 31.

The semiconductor substrate 31 is an insulating substrate or the like, which has a semiconductor layer provided on the surface where the photosensitive region is formed, and is a p-type silicon substrate, for example. The semiconductor substrate 31 has impurity regions 41A, 41B, 41C, 41D, and 41E, and an element isolation region 42 for electrically isolating the unit pixels 200 from each other. The element isolation region 42 is also provided between the impurity regions 41B and 41C. This suppresses leakage of signal charges stored in the charge storage node 24. The element isolation region 42 is formed by implanting acceptor ions under predetermined implantation conditions, for example.

The impurity regions 41A, 41B, 41C, 41D, and 41E are diffusion layers formed in the semiconductor substrate 31, for example. The impurity regions 41A, 41B, 41C, 41D, and 41E are n-type impurity regions. As illustrated in FIG. 6, the amplifier transistor 11 includes the impurity region 41C, the impurity region 41D, a gate insulating film 38B, and the gate electrode 39B. The impurity region 41C and the impurity region 41D serve as a source region and a drain region of the amplifier transistor 11, respectively. A channel region of the amplifier transistor 11 is formed between the impurity region 41C and the impurity region 41D.

Similarly, the address transistor 13 includes the impurity region 41D, the impurity region 41E, a gate insulating film 38C, and the gate electrode 39C. In the example illustrated in FIG. 6, the amplifier transistor 11 and the address transistor 13 are electrically connected to each other by sharing the impurity region 41D. The impurity region 41D and the impurity region 41E serve as a source region and a drain region of the address transistor 13, respectively. The impurity region 41E is connected to the vertical signal line 17 illustrated in FIG. 5.

The reset transistor 12 includes the impurity region 41A, the impurity region 41B, a gate insulating film 38A, and the gate electrode 39A. The impurity region 41A and the impurity region 41B serve as a source region and a drain region of the reset transistor 12, respectively. The impurity region 41A is connected to the reset signal line 27 illustrated in FIG. 5.

The gate insulating film 38A, the gate insulating film 38B, and the gate insulating film 38C are insulating films formed using an insulating material. The insulating film has a single layer structure or a multilayer structure including a silicon oxide film, a silicon nitride film or the like, for example.

The gate electrode 39A, the gate electrode 39B, and the gate electrode 39C are each formed using a conductive material. The conductive material is conductive polysilicon, for example.

The interlayer insulating layer 150 is stacked on the semiconductor substrate 31 so as to cover the amplifier transistor 11, the address transistor 13, and the reset transistor 12. A wiring layer (not illustrated) may be disposed in the interlayer insulating layer 150. The wiring layer is made of metal such as copper, for example, and may partially include wiring such as the vertical signal line 17 described above, for example. The number of insulating layers in the interlayer insulating layer 150 and the number of layers included in the wiring layer disposed in the interlayer insulating layer 150 can be set arbitrarily.

As illustrated in FIG. 1, the photoelectric converter 110 is disposed on the interlayer insulating layer 150. The specific configuration of the photoelectric converter 110 is the same as that in FIG. 1. The terminal electrode 115 illustrated in FIG. 1 is provided not within the unit pixel 200 but at the periphery of the photosensitive region, for example.

A color filter 60 is provided above the photoelectric converter 110. A microlens 61 is provided on the color filter 60. The color filter 60 is formed as an on-chip color filter by patterning, for example. As a material for the color filter 60, a photosensitive resin or the like is used, in which dye or pigment is dispersed. The microlens 61 is provided as an on-chip microlens, for example. As a material for the microlens 61, an ultraviolet photosensitive material or the like is used.

The imaging device 100 can be manufactured using a general semiconductor manufacturing process. Particularly when a silicon substrate is used as the semiconductor substrate 31, the imaging device 100 can be manufactured using various silicon semiconductor processes.

### Other Embodiments

The imaging device according to one or more aspects has been described above based on the embodiments. However, the present disclosure is not limited only to these embodiments. The present disclosure also encompasses various modifications conceived by those skilled in the art to the embodiments and aspects constructed by a combination of the constituent elements in the different embodiments as long as such modifications and aspects do not depart from the scope of the present disclosure.

For example, in the above embodiment, the description is given of the example where the light-shielding film 130 and the functional film 140 contain the same metal clement, but the present disclosure is not limited thereto. The functional film 140 may contain a metal element different from that of the light-shielding film 130. For example, the light-shielding film 130 and the functional film 140 may be a combination of a Ti film and a TaN film, or a combination of a Ta film and a TiN film.

Alternatively, a combination of a tungsten (W) film and a tungsten nitride (WN) film, or a combination of a molybdenum (Mo) film and a molybdenum nitride (MoN) film may be used. The light-shielding film 130 may contain a metal element selected from the group consisting of Ti, Ta, W, and Mo. The functional film 140 may contain a nitride of a metal element selected from the group consisting of Ti, Ta, W, and Mo. The light-shielding film 130 and the functional film 140 may contain the same metal element or may contain different metal elements.

For example, in the above embodiment, the description is given of the two-layer structure of the light-shielding film 130 and the functional film 140 as an example. Alternatively, a four-layer structure may also be adopted by further stacking a light-shielding film made of Ti or Ta and a functional film made of TiN or TaN on the light-shielding film 130 and the functional film 140. That is, another laminate structure of a light-shielding film and a functional film may be further stacked, and the number of laminate structures to be stacked is not particularly limited.

For example, the photoelectric converter 110 may include an electron blocking layer and/or a hole blocking layer. In this case, one of the electron blocking layer and the hole blocking layer is disposed between the photoelectric conversion layer 111 and the transparent electrode 112. The other of the electron blocking layer and the hole blocking layer is disposed between the photoelectric conversion layer 111 and the pixel electrode 113.

The electron blocking layer and the hole blocking layer are formed using known materials. The electron blocking layer and the hole blocking layer may contain organic substances. In this case, a photoelectric conversion material contained in the photoelectric conversion layer 111 may be an inorganic material. The inorganic photoelectric conversion material can be hydrogenated amorphous silicon, a compound semiconductor material, a metal oxide semiconductor material, and the like. The compound semiconductor material is CdSe, for example. The metal oxide semiconductor material is ZnO, for example.

The imaging device 100 does not need to include the protective film 123. In this case, again, deterioration of the light-shielding film 130 can be suppressed by providing the functional film 140.

The respective embodiments described above may be subjected to various modifications, substitution, addition, omission, and the like within the scope of claims or a range equivalent thereto.

The present disclosure can be adapted to an imaging device that can suppress deterioration in performance, and is applicable to a camera, a ranging device, and the like, for example.

What is claimed is:

1. An imaging device comprising:
a semiconductor substrate;
an effective pixel region including an effective pixel;
a non-effective pixel region that is located around the effective pixel region and that does not include the effective pixel;
a photoelectric converter that is located above the semiconductor substrate and that includes a first portion located in the effective pixel region and a second portion located in the non-effective pixel region;
a light-shielding film that is located above the second portion of the photoelectric converter and that contains titanium or tantalum; and
a functional film that is located on the light-shielding film and that is in contact with the light-shielding film, wherein
the functional film has a thickness less than a thickness of the light-shielding film.

2. The imaging device according to claim 1, further comprising:
a protective film that is located on the functional film and that is in contact with the functional film, wherein
a reflectance of the functional film for light transmitted through the protective film is less than a reflectance of the light-shielding film for light transmitted through the protective film when the protective film is in contact with the light-shielding film.

3. The imaging device according to claim 2, wherein
the protective film contains silicon oxynitride.

4. The imaging device according to claim 1, wherein
the functional film and the light-shielding film contain the same metal element.

5. The imaging device according to claim 1, wherein
the functional film contains titanium nitride or tantalum nitride.

6. The imaging device according to claim 1, wherein
the thickness of the functional film is less than half the thickness of the light-shielding film.

7. The imaging device according to claim 1, wherein
the thickness of the light-shielding film is greater than or equal to 200 nm.

8. The imaging device according to claim 1, wherein
the thickness of the functional film is less than or equal to 30 nm.

9. The imaging device according to claim 1, wherein
the photoelectric converter includes
a plurality of first electrodes located above the semiconductor substrate,
a second electrode that is located above the plurality of first electrodes and that faces the plurality of first electrodes, and
a photoelectric conversion layer located between the plurality of first electrodes and the second electrode.
